(19) United States
(12) Patent Application Publication
(10) Pub. No.: US 2023/0178964 A1
(43) Pub. Date: Jun. 8, 2023

(54) Strained Quantum Well Structure, Optical Semiconductor Device, and Semiconductor Laser

(71) Applicant: Nippon Telegraph and Telephone Corporation, Tokyo (JP)

(72) Inventors: Manabu Mitsuhara, Tokyo (JP); Tomonari Sato, Tokyo (JP)

(21) Appl. No.: 17/922,450

(22) PCT Filed: May 25, 2020
(86) PCT No.: PCT/JP2020/020501

§ 371 Date: Oct. 31, 2022

(51) Int. Cl. H01S 5/34; H01S 5/343

(52) U.S. Cl. CPC H01S 5/3406; H01S 5/34313

(57) ABSTRACT

A strained quantum well structure of the present disclosure is a type I strained quantum well structure grown by using an InP crystal as a substrate and including a luminescence wavelength of 1.9 μm or longer and 2.5 μm or shorter, in which a well layer is an InGaAs, InAs, or InGaAsSb crystal including a compression strain, a barrier layer is an InGaAsSb crystal including a tensile strain, and a band discontinuity in a conduction band is 100 meV or greater.

### CROSS-REFERENCE TO RELATED APPLICATIONS

This application is a national phase entry of PCT Application No. PCT/JP2020/020501, filed on May 25, 2020, which application is hereby incorporated herein by reference.

### TECHNICAL FIELD

The present disclosure relates to a high-powered 2 μm-band strained quantum well structure, an optical semiconductor device, and a semiconductor laser.

### BACKGROUND

A gas measurement system by using laser light has characteristics that it is possible to measure a concentration in real time with high precision, and it is further possible to analyze a ratio of isotopes included in a gas. Thus, this gas measurement system has been applied in various fields such as environmental pollution, global warming, food management, medical application, or automotive-related fields.

In the gas measurement by using laser light, a wavelength range near 2 μm is particularly important. FIG. 12 is a diagram showing gas species each having absorption lines in the wavelength range near 2 μm and intensities thereof. In this wavelength range, absorption lines of gas species such as CO₂, N₂O, CH₄, NH₃, and CO are dense, and absorption intensities thereof are greater than an intensity of an absorption line in the wavelength range of 1.625 μm or shorter, which is widely used in optical communications. Thus, when absorption lines are used in the wavelength range near 2 μm, it is possible to measure a gas concentration with high precision.

Furthermore, this wavelength range is one of so-called “atmospheric windows” in which absorption of water is small as shown in FIG. 12 and is also an advantageous wavelength range in propagating light far in the atmosphere. In addition, this wavelength band corresponds to a wavelength region called eye-safe because light having the wavelength band is unlikely to reach the retina of the eye and is commonly safe as compared to the wavelength region of the visible light, even when the light having the wavelength band is transferred in the atmosphere.

In gas measurement of an exhaust facility such as a chimney or a combustion opening, a production/evaluation device, an internal combustion engine and an exhaust device of an automobile, and the like, measurement at multiple points rather than only one point is desirable. In order to perform multi-point measurement by using laser light, it is necessary to prepare an emitting end of light for each point.

Because a laser having an oscillation wavelength of about 2 μm (1.9 μm to 2.5 μm) made by using a strained quantum well on an InP substrate has been developed based on a production technique of a laser for optical communication, it is easily to couple the laser with a fiber, as well as a technique for branching light by using a demultiplexer can be also applied thereto. As a result, when the laser having an oscillation wavelength of about 2 μm on the InP substrate is used for a light source in measuring multiple points, it is not necessary to prepare a plurality of light sources and drive devices, which can reduce the cost of the measuring system. Hereinafter, the laser having an oscillation (luminescence) wavelength of 1.9 μm or longer and 2.5 μm or shorter will be referred to as a “2 μm-band laser”.

In gas measurement by using light, when one point is measured, sufficient precision is often achieved with a light source having an optical power of about several mW. It is relatively easy to obtain an optical power of about several mW by using the laser having an oscillation wavelength of a 2 μm band on the InP substrate.

However, when multiple points are attempted to be measured with one laser, light is divided by the number of measurement points, and in addition, it is necessary to consider a coupling efficiency with a fiber and an optical loss in a fiber or a demultiplexer. For a laser used in multi-point measurement, a laser having a larger optical power as the number of measurement points increases is used.

The light having a wavelength of about 2 μm can be propagated far in the atmosphere because the “atmospheric window” can be utilized, as described above. As a field in which this characteristic can be utilized, there is a light detection and ranging (LIDAR), and a measurement distance to a target object can be increased, as well as a type and a concentration of gas can be measured, by using the 2 μm-band laser. A light source for the LIDAR takes a method in which one laser is basically used to scan its emission direction. This eliminates branching of the laser light as described above.

However, in the light source for the LIDAR, a watt-class optical power is used depending on a type of measurement. Due to this, although the 2 μm-band laser easily propagates in the atmosphere, it is important to make the laser high-powered for applying the laser to the LIDAR to increase the measurement distance and the measurement precision of a gas concentration.

### CITATION LIST

### Non Patent Literature

NPL 1: S. Forouhar, A. Ksendzov, A. Larsson, and H. Temkin, “InGaAs/InGaAsP/InP strained-layer quantum lasers at 2 μm”, Electron. Lett. VOL. 28, NO. 15, 1992, 1431-1432.

NPL 2: M. Mitsuhara, M. Ogasawara, M Oishi, H. Sugiura and K. Kasaya, “2.05 μm wavelength InGaAs—InGaAs distributed-feedback multiquantum-wells lasers with 10-mW output power”, IEEE Photonics Technology Letters, Vol. 11, NO. 1, 1999, 33-35.

NPL 3: T. Sato, M. Mitsuhara, N. Nunoya, T. Fujisawa, K. Kasaya, F. Kano and Y. Kondo, “2.33-μm-wavelength distributed feedback lasers with InAs-Ino. 53Gao. 47As multiple-quantum wells on InP substrates”, IEEE Photonics Technology Letters, VOL. 20, NO. 12, 2008, 1045-10. 47.

### SUMMARY

### Technical Problem

As described above, a high-powered laser is desired for multi-point measurement of gas measurement by using a laser and for lidar application. An optical power of a semiconductor laser on an InP substrate can be increased by contriving a device structure such as a resonator length, a stripe width, a structure of a waveguide, a preparation of an end surface, or adoption of a current constriction structure.

Furthermore, optical power characteristics are improved by a structure and a crystal quality of an active layer (luminescence layer) of a semiconductor laser. When an InGaAs(P) crystal lattice-matching with the InP substrate is used as the active layer, what has the longest luminescence wavelength is InGaAs having a band gap of about 0.74 eV, and its luminescence wavelength is 1.67 μm. The luminescence at the wavelength or longer is difficult because a crystal defect caused by strain stress due to lattice mismatch occurs.

For avoiding this crystal defect, a strained quantum well structure is used in the active layer (luminescence layer). Here, in order to make the luminescence wavelength 2 μm or longer, a strained quantum well structure including a well layer having a compression strain of at least 1.0% or greater is used (see, for example, NPL 1, NPL 2, and NPL 3).

In order to increase a luminance efficiency of the strained quantum well structure, carriers (electrons and holes) injected to the well layer are efficiently subjected to radiative recombination without overflowing from the well layer.

As an index of making a laser high-powered, there is a value indicating a temperature dependence of an oscillation threshold current (hereinafter, referred to as “characteristic temperature”). The characteristic temperature indicates a high value when a laser oscillates at a low threshold current even at an elevated temperature. That is, the higher the characteristic temperature, the more the laser becomes high-powered.

Specifically, in a laser in which carriers do not leak from a well layer and a threshold current is unlikely to increase even at an elevated temperature (laser having a high characteristic temperature of the threshold current), even when an injected current is increased, leakage of carriers is small, which easily makes the laser to support a high power.

However, in a laser having an oscillation wavelength of 2 μm or longer, the characteristic temperature of the threshold current is low as compared to a semiconductor laser for optical communication as described below, and it is difficult to achieve a high power.

FIGS. 13A to 13C are diagrams each schematically illustrating a distribution of carriers (electrons and holes) injected in a multiple quantum well laser, and a case where a layer thickness of a well layer is small and the number of well layers is small in FIG. 13A, a case where a layer thickness of a well layer is small and the number of well layers is large in FIG. 13B, and a case where a layer thickness of a well layer is large and the number of well layers is large in FIG. 13C will be described as examples.

In FIGS. 13A to 13C, a solid line of a well layer indicates a band end when there is no quantum effect, and a dotted line indicates a quantum level taking a quantum effect into account. Carriers can be injected only up to this quantum level. When the layer thickness of the well layer becomes small, the quantum level rises in a conduction band and descends in a valence band.

FIG. 13A illustrates a case where the layer thickness of the well layer is small and the number of well layers is small. When injected electrons are increased, electrons overflow from the well layer, making it difficult to subject electrons to radiative recombination in the well layer. In addition, a temperature near the active layer rises when injected electrons are increased, and thus, a situation in which when a current is further injected, an optical power is adversely reduced is more likely to occur. In a laser by using a quantum well as the active layer, electrons easily leak from the well layer due to temperature rise, and in such a laser, the characteristic temperature of the threshold current is also low.

FIG. 13B illustrates a case in which the number of well layers is increased as compared to FIG. 13A. In this case, as compared to FIG. 13A, the overflow of electrons from the well layer is small, but an energy difference between a quantum level of the conduction band in the well layer (exactly, first level) and a bottom of the conduction band in a barrier layer (referred to as a band discontinuity in the conduction band) is small, and thus electrons are likely to overflow from the well layer, and the high power is also difficult to achieve in this case.

FIG. 13C illustrates a case in which the layer thickness of the well layer is further increased as compared to FIG. 13B. In this case, the band discontinuity in the conduction band increases and the overflow of electrons from the well layer can be suppressed, which can increase the optical power as compared to the cases in FIGS. 13A and 13B. In this case, the characteristic temperature of the threshold current is also increased. To achieve the high power of the laser, the well layer thickness is increased and the number of well layers is increased as in FIG. 13C.

As described above, in the 2 μm-band semiconductor laser by using an InP-based crystal, it is a challenge to increase the layer thickness of the well layer and the number of layers in the strained quantum well structure and increase the band discontinuity in the conduction band.

### Means for Solving the Problem

In order to solve the problems described above, a strained quantum well structure according to an aspect of the present disclosure is a strained quantum well structure of a type I being grown by using an InP crystal as a substrate, including a luminescence wavelength of 1.9 μm or longer and 2.5 μm or shorter, and including a well layer being an InGaAs, InAs, or InGaAsSb crystal including a compression strain, a barrier layer being an InGaAsSb crystal including a tensile strain, and a band discontinuity in a conduction band being wo meV or greater.

### Effects of Embodiments of the Invention

According to the present disclosure, a strained quantum well structure and an optical semiconductor device such as a semiconductor laser of a 2 μm wavelength band can be made high-powered.

### BRIEF DESCRIPTION OF THE DRAWINGS

FIG. 1 is a diagram illustrating an InGaAs well layer thickness dependence for describing a strained quantum well structure according to a first embodiment of the present disclosure.

FIG. 2 is a diagram illustrating an InAs well layer thickness dependence for describing the strained quantum well structure according to the first embodiment of the present disclosure.

FIG. 3A is a schematic view of a band alignment of a conduction band and a valence band for describing the strained quantum well structure according to the first embodiment of the present disclosure.

FIG. 3B is a schematic view of a band alignment of the conduction band and the valence band for describing the strained quantum well structure according to the first embodiment of the present disclosure.

FIG. 4 is an overview of the strained quantum well structure according to the first embodiment of the present disclosure.

FIG. 5 is a schematic view of the band alignment of the conduction band and the valence band in the strained quantum well structure according to the first embodiment of the present disclosure.

FIG. 6 is a diagram illustrating an InGaAs well layer thickness dependence in the strained quantum well structure according to the first embodiment of the present disclosure.

FIG. 7 is a diagram illustrating an Sb composition proportion dependence of a band gap of GaAsSb for describing the strained quantum well structure according to the first embodiment of the present disclosure.

FIG. 8 is a diagram illustrating an InAs well layer thickness dependence in a strained quantum well structure according to a second embodiment of the present disclosure.

FIG. 9 is an overview of a layer structure of a semiconductor laser according to a third embodiment of the present disclosure.

FIG. 10 is a diagram illustrating an X-ray diffraction measurement result of a strained quantum well crystal used for a semiconductor laser according to the third embodiment of the present disclosure.

FIG. 11 is a diagram illustrating a photoluminescence measurement result of the strained quantum well crystal used for the semiconductor laser according to the third embodiment of the present disclosure.

FIG. 12 is a diagram illustrating an optical absorption spectrum of water (H₂O) and an absorption range of each gas species.

FIG. 13A is a schematic diagram of an injected carrier distribution in a multiple quantum well laser in the related art.

FIG. 13B is a schematic diagram of the injected carrier distribution in the multiple quantum well laser in the related art.

FIG. 13C is a schematic diagram of the injected carrier distribution in the multiple quantum well laser in the related art.

### DETAILED DESCRIPTION OF ILLUSTRATIVE EMBODIMENTS

### First Embodiment

Next, a strained quantum well structure according to a first embodiment of the present disclosure will be described with reference to FIGS. 1 to 7. The strained quantum well structure according to the present embodiment supports a high power of a 2 μm-band semiconductor laser by using an InP-based crystal.

First, a well layer in the strained quantum well structure will be considered. FIG. 1 illustrates a well layer thickness dependence of band discontinuity in a conduction band when InGaAs is used for a well layer in a strained quantum well structure of a type I. For the well layer, InGaAs having a compression strain of 1.65% was used, and for a barrier layer, InGaAs lattice-matching with InP was used. A luminescence wavelength is in a 2 μm wavelength band of 1.9 μm or longer and 2.5 μm or shorter.

With an increase of a layer thickness of the well layer, the band discontinuity in the conduction band is increased, so that band discontinuity of about 100 meV at a layer thickness of 12 nm can be obtained. Band discontinuity in a valence band at this time is about 50 meV. In a laser actually made by using this strained multiple quantum well structure, an oscillation wavelength of about 2.05 μm is obtained when the well layer thickness is 11.5 nm and the number of well layers is 4 (NPL 2). However, a characteristic temperature of a threshold current of the laser is about 50 K, and the characteristic temperature is small as compared to a high-powered laser for optical communication. From this result, it is difficult to make a laser high-powered when the band discontinuity in the conduction band is less than 100 meV.

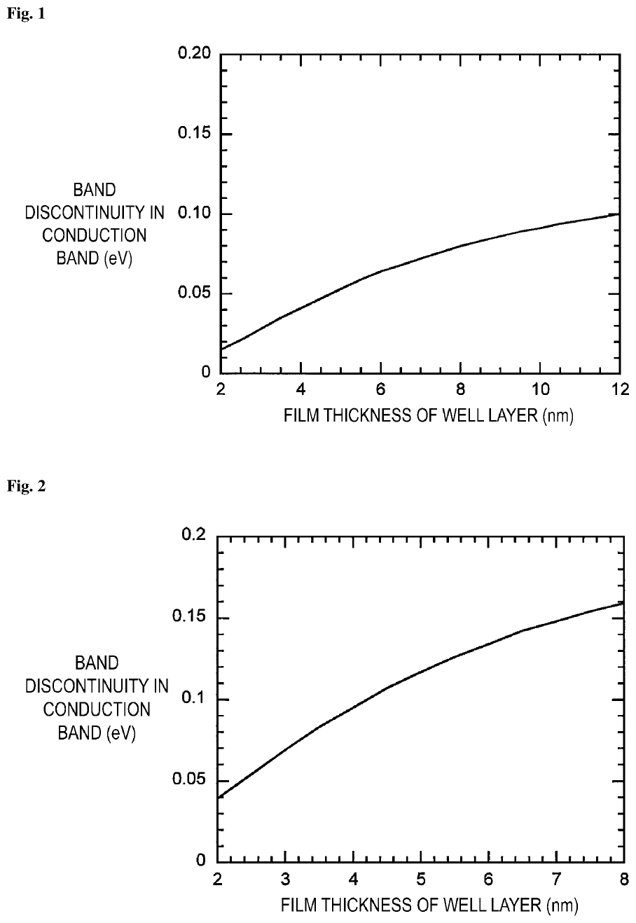

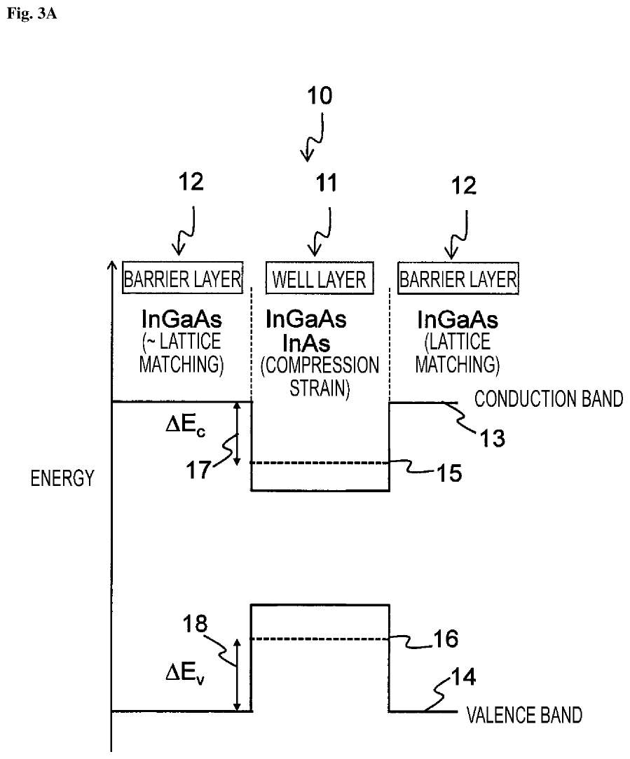

FIG. 2 illustrates a well layer thickness dependence of band discontinuity in the conduction band when InAs is used for the well layer in the strained quantum well structure. InAs was used for the well layer, and InGaAs lattice-matching with InP was used for the barrier layer.

With an increase of the layer thickness of the well layer, the band discontinuity in the conduction band is increased, so that band discontinuity of 100 meV or greater can be obtained at a layer thickness of 5 nm or greater. In a laser actually made by using this strained multiple quantum well structure, a characteristic temperature of 71 K is obtained when the well layer thickness is 5 nm and the number of well layers is 4 (NPL3). This result indicates that a laser can be made high-powered when the band discontinuity in the conduction band is 100 meV or greater.

However, as long as InAs is used for the well layer, a compression strain of InAs on the InP substrate is 3.2%, which is large, so that it is difficult to make the layer thickness 5 nm or greater and to make the number of well layers 4 or more. It is also difficult to freely select an oscillation wavelength (luminescence wavelength) in a wavelength range of 2 μm or longer.

Next, the barrier layer in the strained quantum well structure will be considered. As described above, for making a laser high-powered, the band discontinuity in the conduction band when the barrier layer is InGaAs lattice-matching with InP is to be about 100 meV for the InGaAs well layer, and 100 meV or greater for the InAs well layer. Given that a band gap of InGaAs lattice-matching is about 0.74 eV, it is believed that the barrier layer in the strained quantum well structure has a band gap of at least about 0.74 meV in order to make the band discontinuity in the conduction band 100 meV or greater.

Furthermore, in a well layer having the compression strain of the strained quantum well structure, a compressive strain stress increases when the layer thickness is increased, and the number of layers is increased. As such, a strain-compensated quantum well structure is employed in which a tensile strain in a direction opposite to that of the compression strain is applied to the barrier layer to reduce a strain amount as an average of the entire quantum well structure.

However, when a tensile strain is applied to InGaAs or InGaAsP used for the barrier layer in the 2 μm-band laser, fluctuation of the layer thickness is likely to occur, so that it is difficult to apply the strain-compensated quantum well structure (e.g., M. Mitsuhara, M. Ogasawara, and H. Sugiura, “Effect of strain in barrier layer on structural and optical properties pf highly strained Ino. 77Gao. 23As/InGaAs multiple quantum wells”, Journal of Crystal Growth, VOL. 210, 2000, 463-470. A. Ponchet, A. Le Corre, A. Godefroy, S. Salaun, and A. Poudoulec, “Influence of stress and surface reconstruction on the morphology of tensile InGaAs grown on InP (001) by gas source molecular beam epitaxy”, Journal of Crystal Growth, VOL. 153, 1995, 71-80. P. Kroner, H. Baumeister, J. Rieger, E. Veuhoff, O. Marti, and H. Heinecke, “Comparison of structural and optical properties in strained GaInAsP MQW structures grown by MOVPE and MOMBE”, Journal of Crystal Growth, VOL. 209, 2000, 424-430). Thus, in the current 2 μm-band laser, InGaAs or InGaAsP, which substantially lattice-matches with InP, is often used as the barrier layer (e.g., NPL 2 and NPL 3. Or T. Sato, M. Mitsuhara, T. Kakitsuka, T. Fujisawa, and Y. Kondo, “Metalorganic vapor phase epitaxial growth of InAs/InGaAs multiple quantum well structures on InP substrates”, IEEE Journal of Selected Topics in Quantum Electronics, VOL. 14, NO. 4, 2008, 992-997. D. Serries, M. Peter, R. Kiefer, K. Winkler, and J. Wagner, “Improved performance of 2 μm InGaAs strained quantum-well lasers on InP by increasing carrier confinement”, IEEE Photonics Technology Letters, VOL. 13, NO. 5, 2001, 412-414).

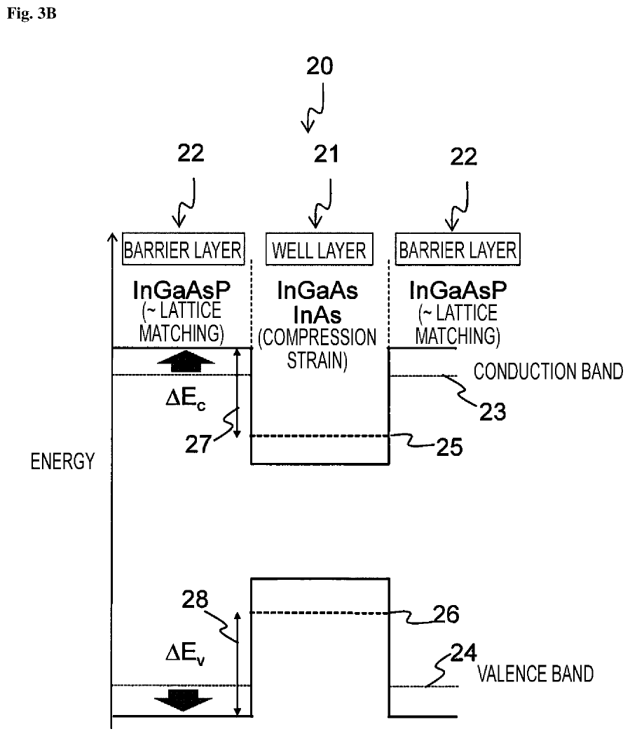

FIG. 3A schematically illustrates a band alignment of the conduction band and the valence band in the strained quantum well structure in a case where the barrier layer is InGaAs lattice-matching with InP, and FIG. 3B schematically illustrates a band alignment of the conduction band and the valence band in the strained quantum well structure in a case where the barrier layer is InGaAsP lattice-matching with InP. Well layers 11 and 21 each were compression strain InGaAs or InAs.

As described above, energy differences between quantum levels (exactly, first levels) 15 and 25 of conduction bands 13 and 23 in the well layers 11 and 21 and bottoms of the conduction bands 13 and 23 in the barrier layers 12 and 22 each are a band discontinuity (ΔEc) 17 in the conduction band, and energy differences between quantum levels (exactly, the first levels) 16 and 26 of the valence bands 14 and 24 in the well layers 11 and 21 and peaks of the valence bands 14 and 24 in the barrier layers 12 and 22 each are a band discontinuity (ΔEv) 18 in the valence band.

As illustrated in FIG. 3B, when InGaAsP is used for the barrier layer 22, the band discontinuity 27 in the conduction band can be increased (arrow in the drawing).

However, the band discontinuity 28 in the valence band is also increased simultaneously. A hole has a large effective mass as compared to an electron and is difficult to move. Thus, when the band discontinuity 28 in the valence band is increased and the number of well layers is also increased, the number of holes in the well layers 21 on the p side is increased, and holes are non-uniformly injected to each of the well layers 21.

When the non-uniform injection of holes becomes significant, radiative recombination with electrons is less likely to occur in the well layers 21 having a small hole concentration. Thus, even when InGaAsP is actually used for the barrier layer 22, it is difficult to obtain a characteristic temperature of 50 K or higher (e.g., D. Serries, M. Peter, R. Kiefer, K. Winkler, and J. Wagner, “Improved performance of 2 μm InGaAs strained quantum-well lasers on InP by increasing carrier confinement”, IEEE Photonics Technology Letters, VOL. 13, NO. 5, 2001, 412-414. M. Oishi, M. Yamamoto, and K. Kasaya, “2.0-μm single-mode operation of InGaAs—InGaAsP distributed-feedback buried-heterostructure quantum-well lasers”, IEEE Photonics Technology Letters, VOL. 9, No. 4, 1997, 431-433). In this way, even when InGaAsP is used for the barrier layer 22, it is difficult to obtain a high power with the laser having an oscillation wavelength of 2 μm or longer.

Note that the lower limit of the band discontinuity in the valence band only need be 0 meV or greater in consideration of the condition of the strained quantum well structure of the type I.

As described above, in making the 2 μm-band laser by using the InP-based crystal high-powered, the band discontinuity in the conduction band is increased, as well as the band discontinuity in the conduction band is reduced. An energetic position of the peak of the valence band in a Group III to V compound semiconductor is highly dependent on a Group V element included in the semiconductor. Specifically, a position of the peak of the valence band of InGaAs falls when P is added as the Group V element, and rises when Sb is added. Thus, the band discontinuity in the valence band is increased when InGaAsP is used instead of InGaAs for the barrier layer, while it can be reduces when InGaAsSb is used for the barrier layer.

However, in a condition for lattice-matching with InP, a band gap of InGaAsSb is smaller than that of InGaAs, so that it is difficult to increase the band discontinuity of the conduction band even when InGaAsSb lattice-matching with InP is used. On the other hand, if a Ga composition is increased in InGaAsSb more than the condition for lattice-matching with InP, it is possible to increase the band gap.

In this way, when the Ga composition is increased in InGaAsSb, a tensile strain is applied to the crystal. In InGaAsSb, unlike InGaAs, even in a state where the tensile strain is applied, fluctuation of the layer thickness is suppressed (Mitsuhara, Ohiso, “Strain-compensated InGaAs(Sb)/InGaAs(Sb) MQW for 2 μm wavelength”, The 78th Japan Society of Applied Physics Autumn Meeting, 2017, 5p-C21-10). This is due to a surfactant effect of Sb included in InGaAsSb. The surfactant effect of Sb is an effect that InGaAs not including Sb does not have.

Thus, InGaAsSb is used for the barrier layer of the strained quantum well structure according to the present embodiment. A detailed configuration of the strained quantum well structure according to the present embodiment will be described below.

Configuration of Strained Quantum Well Structure

The strained quantum well structure conceived on the basis of the above guideline will be described.

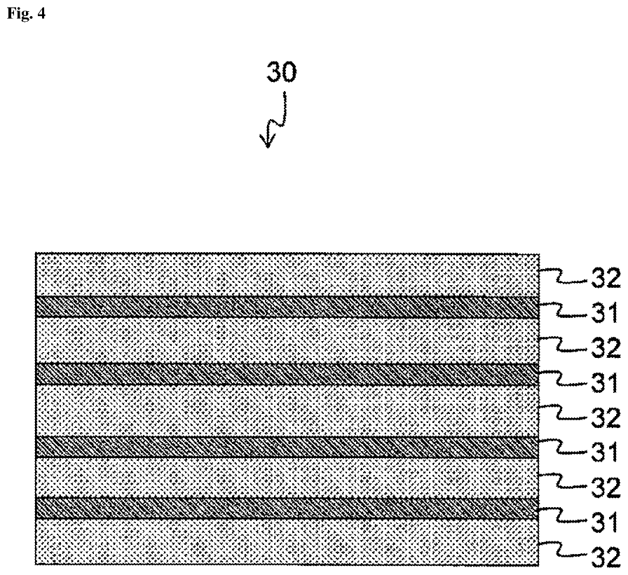

FIG. 4 illustrates an example of a strained quantum well structure 30 according to the present embodiment. The strained quantum well structure is grown on an InP substrate (not illustrated), and a well layer 31 is, for example, In₁₋ₓGaₓAs_{1-y}Sb_{y} (x=0.67, y=0.1), and has a compression strain of 1.65%. For a barrier layer 32, for example, In₁₋ₓGaₓAs_{1-y}Sb_{y} (x=0.37, y=0.1) having a tensile strain of 0.4% is used. Alternatively, for the barrier layer 32, In₁₋ₓGaₓAs_{1-y}Sb_{y} (x=0.28, y=0.1) having a tensile strain of 1.0% may be used.

Here, an Sb composition proportion is substantially the same (constant) and a Ga composition proportion differs between the well layer 31 and the barrier layer 32. In FIG. 4, it is considered to be the quantum well structure is commonly more easily made when a Group V composition proportion is the same and a Group III composition proportion is varied, but the Sb composition proportion need not be the same. This is because, it is important that Sb is present on the growth surface at the time of crystal growth for the surfactant effect, and Sb (Sb composition proportion) taken into a film from the growth surface is not essential for the surfactant effect.

For the well layer 31, In₁₋ₓGaₓAs_{1-y}Sb_{y} (x=0.67, y=0.1) is used, but this is not a limitation, and InGaAs or InAs may be used.

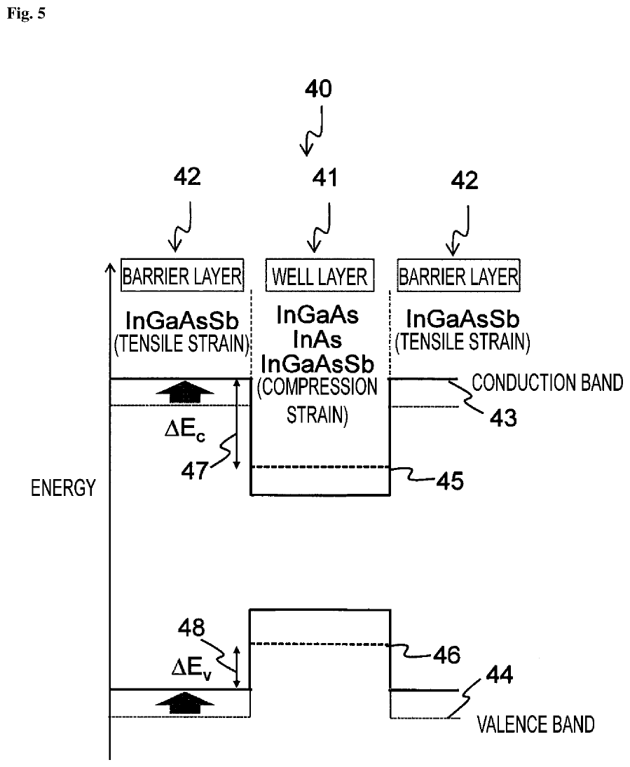

FIG. 5 illustrates a schematic diagram of band alignment of the conduction band and the valence band of the strained quantum well structure according to the present embodiment. A case is illustrated in which InGaAsSb having a tensile strain is used for a barrier layer 42, and InGaAs, InAs, or InGaAsSb is used for a well layer 41.

When InGaAsSb having a tensile strain is used for the barrier layer 42, a band discontinuity 47 of the conduction band can be increased without increasing a band discontinuity 48 in the valence band, as compared to the case where InGaAs lattice-matching with InP is used (FIG. 3A).

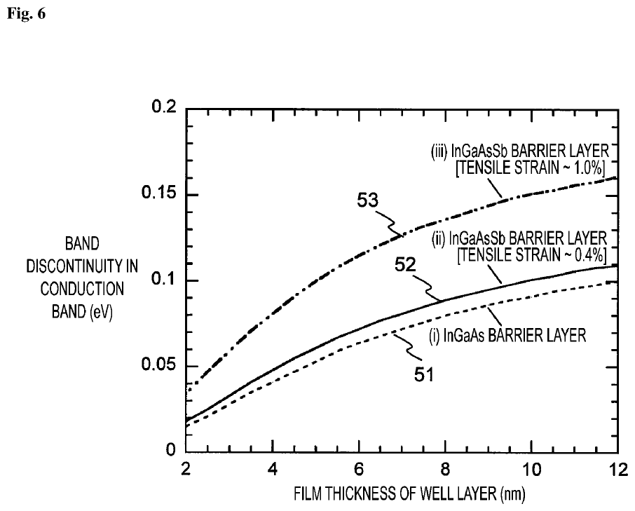

Next, the band discontinuity of the conduction band in the strained quantum well structure according to the present embodiment will be quantitatively described. FIG. 6 illustrates changes in band discontinuity in the conduction band depending on the well layer thickness in the strained quantum well structure according to the present embodiment. Calculation was performed using an effective mass approximation model common in the calculation of quantum levels in consideration of a shift of a band end due to a lattice strain and a quantum size effect. InGaAs having a compression strain of 1.65% was used for the well layer.

A solid line 52 indicates a case where the barrier layer is In₁₋ₓGaₓAs_{1-y}Sb_{y} (x=0.37, y=0.1) having a tensile strain of 0.4%. A single-dot dash line 53 indicates a case where the barrier layer is In₁₋ₓGaₓAs_{1-y}Sb_{y} (x=0.28, y=0.1) having a tensile strain of 1.0%. For comparison, a dotted line 51 indicates a case where the barrier layer is InGaAs lattice-matching with InP.

In the case where InGaAs lattice-matching with InP is used for the barrier layer, as described above (FIG. 1), with increase of the layer thickness of the well layer, the band discontinuity in the conduction band is increased, so that a band discontinuity of about 100 meV can be obtained at a layer thickness of 12 nm. In this case, a laser having an oscillation wavelength of about 2.05 μm is obtained at a well layer thickness of 11.5 nm.

When In₁₋ₓGaₓAs_{1-y}Sb_{y} (x=0.37, y=0.1) having a tensile strain of 0.4% is used for the barrier layer, the band gap of the barrier layer is equivalent to the band gap of InGaAs lattice-matching with InP (about 0.74 eV). In this case, with increase of the layer thickness of the well layer, the band discontinuity in the conduction band is increased, so that a band discontinuity of 100 meV or greater can be obtained at a layer thickness of about 10 nm or greater.

When In₁₋ₓGaₓAs_{1-y}Sb_{y} (x=0.28, y=0.1) having a tensile strain of 1.0% is used for the barrier layer, with increase of the layer thickness of the well layer, the band discontinuity in the conduction band is increased, so that a band discontinuity of 100 meV or greater can be obtained at a layer thickness of about 5 nm or greater. Furthermore, a band discontinuity of 150 meV or greater can be obtained at a layer thickness of about 10 nm ore greater, and a band discontinuity of 160 meV can be obtained at a layer thickness of 12 nm.

Here, when InGaAsSb having a tensile strain of 0.4% or 1.0% is used, a compression strain of the well layer can be reduced (strain-compensated) throughout the quantum well structure. As a result, the upper limit of the number of well layers is about four when InGaAs lattice-matching with InP is used for the barrier layer, while the number of well layers can be increased to four or more by using InGaAsSb having a tensile strain for the barrier layer.

In addition, the band gap of InGaAsSb is decreased when the Sb composition proportion and the In composition proportion are increased. Thus, upper limits of the Sb composition proportion and the In composition proportion are present in order to make the band gap of InGaAsSb 0.74 eV or greater.

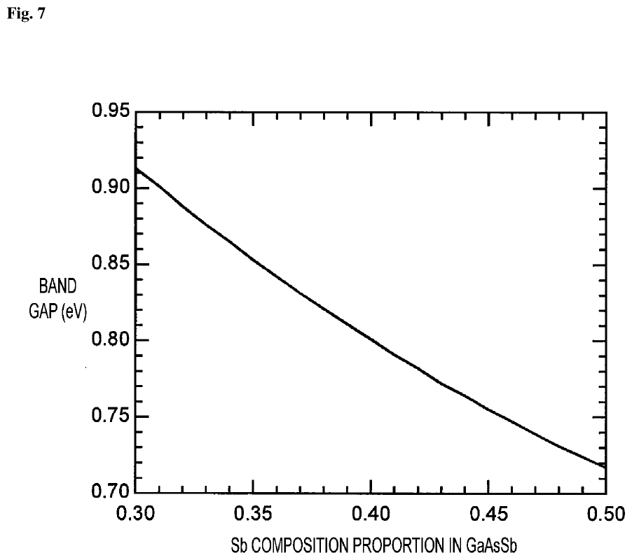

When an As composition proportion and the Sb composition proportion are fixed in InGaAsSb, the band gap becomes the largest in a case of GaAsSb where the In composition proportion is 0. FIG. 7 illustrates an Sb composition proportion dependence of the band gap of GaAsSb. In order to make the band gap of GaAsSb 0.74 eV or greater, the Sb composition proportion is 0.47 or less.

For this reason, when InGaAsSb having a tensile strain is used for the barrier layer, the Sb composition proportion is desirably at least 0.47 or less.

Next, a lower limit of the Sb composition proportion will be described. As described above, in InGaAsSb, the surfactant effect of Sb suppresses fluctuation of the layer thickness even when a tensile strain is applied. This surfactant effect is effective if Sb is included in a crystal even in a small amount. Thus, in InGaAsSb, Sb only needs to be included even in a small amount, and the Sb composition proportion only needs to be greater than 0.

As described above, when InGaAsSb having a tensile strain is used for the barrier layer, the well layer thickness and the number of well layers can be increased, and the band discontinuity in the conduction band can be made to be 100 meV or greater, so that it is possible to make the 2 μm-band laser high-powered.

### Second Embodiment

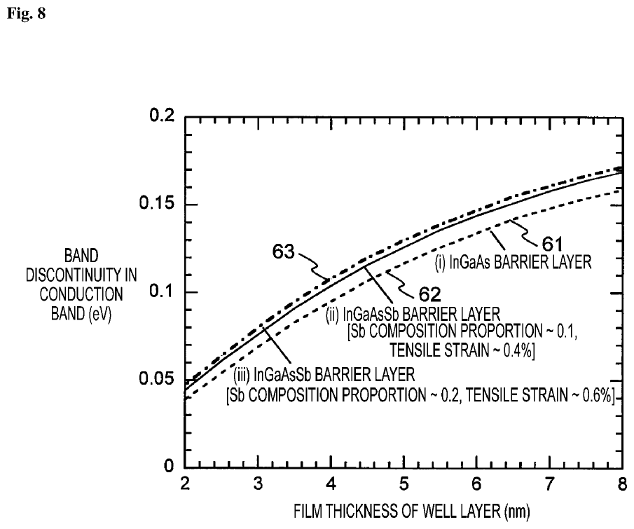

A strained quantum well structure according to a second embodiment of the present disclosure will be described with reference to FIGS. 8 to 12.

The strained quantum well structure according to the present embodiment has substantially the same configuration as that of the first embodiment, but InAs was used for a well layer. When InP is used for the substrate to grow InAs, a compression strain of InAs is 3.2%.

FIG. 8 illustrates changes in band discontinuity in the conduction band depending on the well layer thickness in the strained quantum well structure according to the present embodiment. A solid line 62 indicates a case where a barrier layer is In₁₋ₓGaₓAs_{1-y}Sb_{y} (x=0.37, y=0.1) having a tensile strain of 0.4%. A single-dot dash line 6₃ indicates a case where the barrier layer is In₁₋ₓGaₓAs_{1-y}Sb_{y} (x=0.23, y=0.2) having a tensile strain of 0.6%. For comparison, a dotted line 61 indicates a case where the barrier layer is InGaAs lattice-matching with InP.

When InGaAs lattice-matching with InP is used for the barrier layer, as described above (FIG. 2), with increase of the layer thickness of the well layer, the band discontinuity in the conduction band is increased, so that a band discontinuity of 100 meV or greater can be obtained at a layer thickness of 4.2 nm or greater.

When In₁₋ₓGaₓAs_{1-y}Sb_{y} (x=0.37, y=0.1) having a tensile strain of 0.4% is used for the barrier layer, the band discontinuity in the conduction band is increased by about 10 meV regardless of the well layer thickness, as compared to the case where InGaAs lattice-matching with InP is used for the barrier layer. The band discontinuity in the conduction band is increased to 100 meV at a well layer thickness of 4 nm and is increased to about 170 meV at a well layer thickness of 8 nm.

Here, the composition of the InGaAsSb barrier layer is a composition with which substantially the same band gap as the band gap of InGaAs (about 0.74 eV) is obtained, as described above.

When In₁₋ₓGaₓAs_{1-y}Sb_{y} (x=0.23, y=0.2) having a tensile strain of 0.6% is used for the barrier layer, the band discontinuity in the conduction band is increased with increase of the well layer thickness, as with the case where In₁₋ₓGaₓAs_{1-y}Sb_{y} (x=0.37, y=0.1) having a tensile strain of 0.4% is used for the barrier layer. Here, the Sb composition proportion in In₁₋ₓGaₓAs_{1-y}Sb_{y} was set to 0.2 to increase a tensile strain, so that the band gap was adjusted to be substantially equal to the band gap of InGaAs (about 0.74 eV).

As described above, even when InAs is used for the well layer, the well layer thickness and the number of well layers can be increased by using InGaAsSb having a tensile strain for the barrier layer, so that the band discontinuity in the conduction band can be made to be 100 meV or greater.

Furthermore, the band gap is made to be substantially equal to the band gap of InGaAs (about 0.74 eV) in order not to affect the oscillation wavelength (luminescence wavelength), and thus the well layer thickness and the number of well layers can be increased even when the Sb composition is changed, so that it is possible to make the band discontinuity in the conduction band 100 meV or greater.

As described above, according to the strained quantum well structure of the present embodiment, the 2 μm-band laser can be made high-powered.

In the strained quantum well structures according to the first and second embodiments, InGaAs and InAs are used for the well layer, but this is not a limitation and InGaAsSb may be used. When InGaAsSb having a tensile strain is used for the barrier layer, light having a wavelength corresponding to the oscillation wavelength of the 2 μm-band laser only needs to be emitted, the well layer thickness and the number of well layers only needs to be increased, and the band discontinuity in the conduction band only needs to be made to be 100 meV or greater.

### Third Embodiment

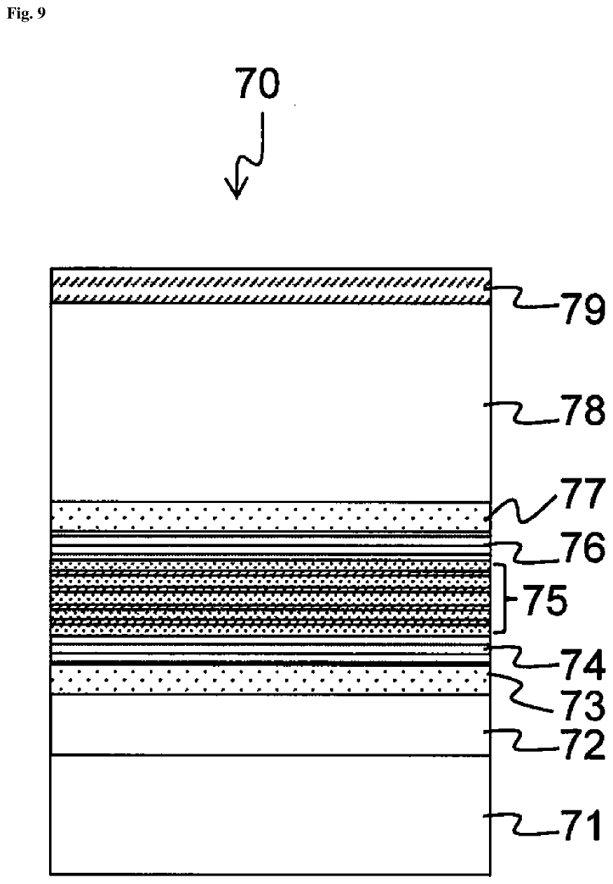

A semiconductor laser according to a third embodiment of the present disclosure will be described with reference to FIGS. 9 to 11.

Configuration of Semiconductor Laser

FIG. 9 illustrates a layer structure of a semiconductor laser according to the present example. An n-type InP buffer layer 72 having a layer thickness of 0.5 μm is grown on an n-type InP substrate 71. Subsequently, an InGaAsP light confinement layer 73 having a layer thickness of 0.1 μm and a band gap wavelength of 1.1 μm and an InGaAsP light confinement layer 74 having a layer thickness of 0.05 μm and a band gap wavelength of 1.3 μm are grown, and then an InGaAsSb/InGaAsSb strained multiple quantum well structure 75, which serves as an active layer, is grown. An InGaAsP light confinement layer 76 having a layer thickness of 0.05 μm and a band gap wavelength of 1.3 μm and an InGaAsP light confinement layer 77 having a layer thickness of 0.1 μm and a band gap wavelength of 1.1 μm are grown on the strained multiple quantum well structure 75, and then a p-type InP cladding layer 78 having a layer thickness of 2.0 μm is grown. Finally, a p-type InGaAs contact layer 79 is grown. Crystal growth is performed by using an organic metal molecular beam epitaxy method at a substrate temperature of 500° C.

First, crystal quality of the strained multiple quantum well structure 75 used for the semiconductor laser will be described. For evaluation of the crystal quality, in the layer structure described above, a crystal composed of layers from the substrate 71 to the InGaAsSb/InGaAsSb strained multiple quantum well structure 75 serving as the active layer was used. This strained multiple quantum well structure 75 is composed of four In₁₋ₓGaₓAs_{1-y}Sb_{y} (x=0.75, y=0.1) well layers and five In₁₋ₓGaₓAs_{1-y}Sb_{y} (x=0.37, y=0.1) barrier layers. A supplied amount of a raw material is adjusted such that the Sb composition proportion of the well layer and the barrier layer is 0.1, and the Ga composition proportion is different between the well layer and the barrier layer.

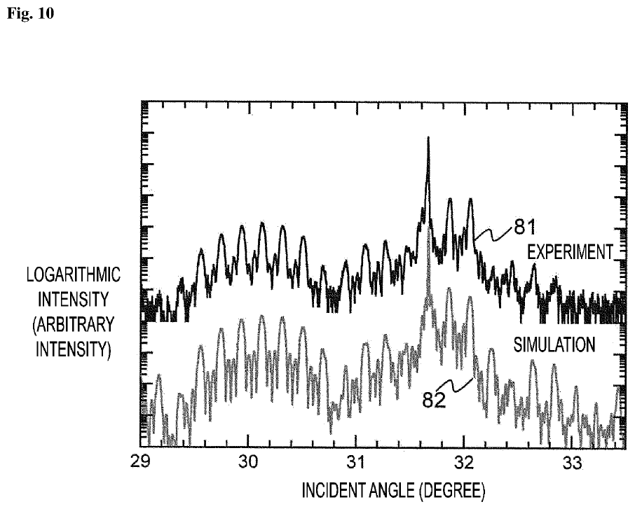

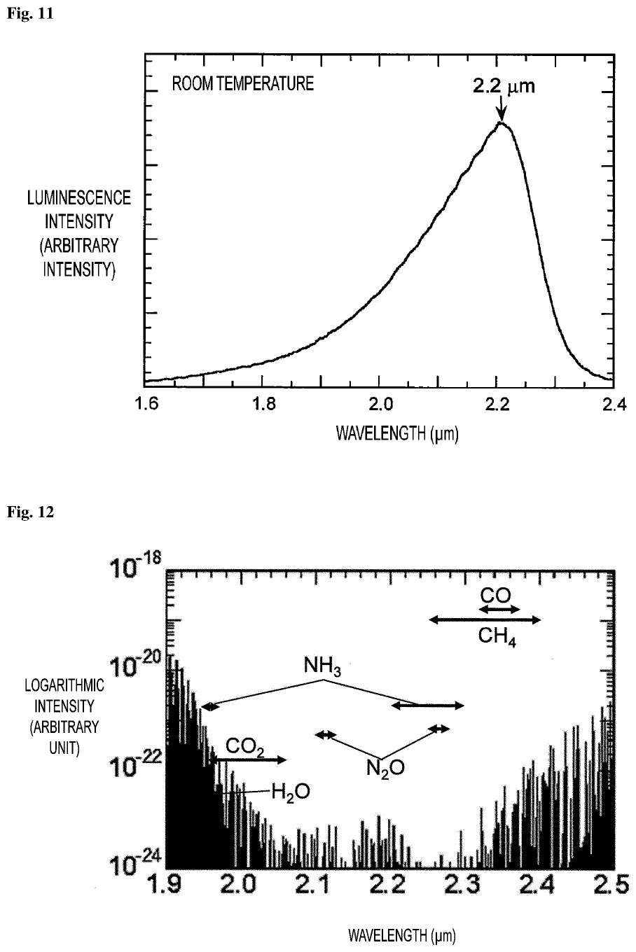

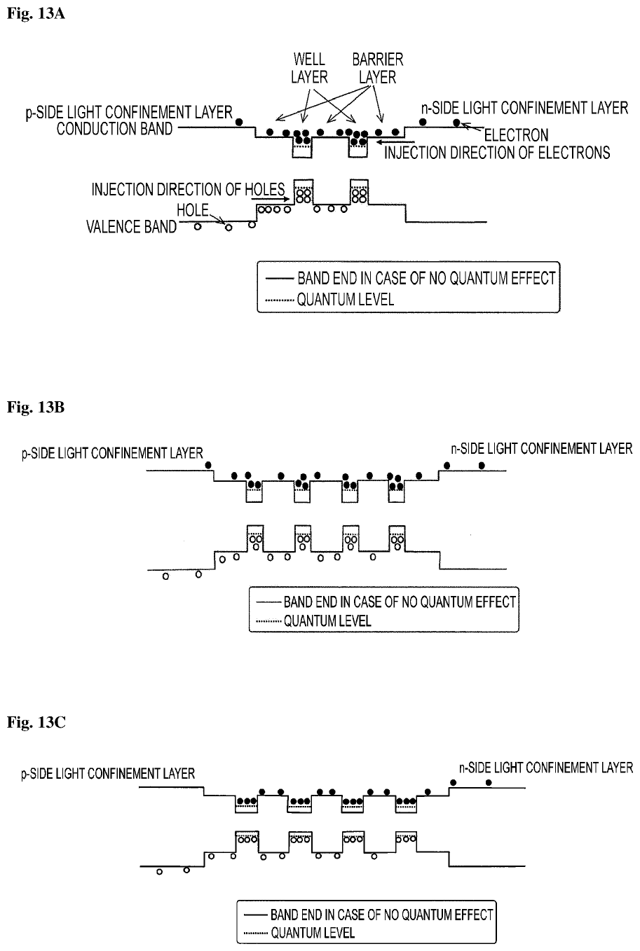

FIG. 10 is a diagram in which a measurement result 81 of an X-ray diffraction pattern of a crystal for evaluation and a simulation result 82 of the crystal for evaluation are compared to each other. As a result of analysis, it was found that the InGaAsSb well layer had a compression strain of 2.3% and a layer thickness of 6.7 nm, and the InGaAsSb barrier layer had a tensile strain of 0.40% and a layer thickness of 20.0 nm. The band gap of InGaAsSb having an Sb composition proportion of 0.1 and a tensile strain of 0.4% is 0.75 eV.

With this combination of the InGaAsSb well layer (the Sb composition proportion of 0.1 and the compression strain of 2.3%) and the InGaAsSb barrier layer (the Sb composition proportion of 0.1 and the tensile strain of 0.4%), the band discontinuity in the conduction band is about 120 meV that is sufficiently greater than 100 meV, which is obtained by calculation.

Note that the simulation of the X-ray diffraction pattern in FIG. 10 was performed assuming that there was no fluctuation in the layer thickness. Thus, favorable match between the measurement result 81 and the simulation result 82 indicates that fluctuation in the layer thickness is suppressed in the InGaAsSb/InGaAsSb strained multiple quantum well structure.

As described above, when InGaAsSb having a tensile strain is used for the barrier layer, a film quality degradation of the active layer due to fluctuation in the layer thickness or the like can be suppressed, and in addition, the band discontinuity in the conduction band can be made to be 100 meV or greater.

Production Method of Semiconductor Laser

The semiconductor laser was produced in normal processes as described below. First, a silicon oxide film is formed on a crystal surface of the layer structure illustrated in FIG. 9.

Next, the silicon oxide film in a region having a width of 40 μm is removed in a striped manner.

Next, a metal for a p-type electrode is deposited onto the striped region exposing the p-type InGaAs contact layer 79, followed by heat treatment to form a p-type electrode.

Next, a back surface of the InP substrate 71 is polished thinly.

Finally, a metal for an n-type electrode is deposited on the back surface, followed by heat treated to form an n-type electrode.

The laser structure is a Fabry-Perot laser in which a resonator is formed by a cleavage, and a resonator length is 600 μm.

Characteristics of Semiconductor Laser

For characteristic evaluation of the semiconductor laser, a laser structure in a cleaved state is used without processing such as coating on an end surface. As a result of measuring the characteristics of the Fabry-Perot laser, a threshold current at an operating temperature of the laser of 25° C. is 350 mA. An oscillation peak wavelength when an injected current is 400 mA is 2.2 μm the same as the peak wavelength of the photoluminescence illustrated in FIG. 11.

The characteristic temperature when the operating temperature is changed from 15° C. to 65° C. is 65 K. Furthermore, laser oscillation is obtained even when the operating temperature exceeds 75° C.

In the related art, in a laser having an oscillation wavelength of 2.2 μm on an InP substrate, a high characteristic temperature and a high operating temperature as in the present example have almost not been reported. The high characteristic temperature and the high operating temperature indicate that leakage of electrons from the well layers is small.

As described above, in the semiconductor laser according to the present example, the well layer thickness and the number of well layers are increased, and the band discontinuity in the conduction band is made to be 100 meV or greater, so that leakage of electrons from the well layers can be reduced to improve the laser characteristics.

As described above, the leakage of electrons from the well layers can be reduced, and thus the proportion of the radiative recombination of electrons and holes in the well layers does not decrease even when the injected current is increased, so that it is possible to easily make the semiconductor laser high-powered.

Although a production example of the Fabry-Perot laser has been described in the present embodiment, a gain peak wavelength of an active layer by using the strained quantum well structure is not significantly changed even when the active layer is applied to a distribution feedback laser, a distributed reflective laser, a laser having an embedded structure, a ridge waveguide laser, or the like, and thus, it goes without saying that application of the active layer according to the present disclosure to a laser structure other than the Fabry-Perot laser is also useful for lengthening an oscillation wavelength.

Although in the present embodiment, the case has been described in which the organic metal molecular beam epitaxy method is used as a method for producing the strained quantum well structure, the present disclosure only needs to be a growing method capable of producing the well layer and the barrier layer described above, and it goes without saying that a case where another growing method such as an organic metal vapor epitaxy method or a molecular beam epitaxy method is used is also effective.

In the embodiments according to the present disclosure, a case has been described in which the number of well layers of the strained multiple quantum well structure serving as an active layer is four, but unlike the strained quantum well structure used in the 2 μm-band laser in the related art, the strained quantum well structure according to the present disclosure has a strain-compensated structure. Thus, it goes without saying that it is easy to make the number of well layers 4 or more and the number of the well layers is not limited to 4.

An example has been described in which the strained quantum well structure according to the present disclosure is applied to a semiconductor laser, but the strained quantum well structure can be also applied to an optical semiconductor device such as a semiconductor optical receiver, a modulator, and a switch in addition to the semiconductor laser.

In the embodiments of the present disclosure, an example of the structure, the size, the material, and the like of each of components has been described in the configurations and the production method of the strained quantum well structure and the optical semiconductor device such as the semiconductor laser, but the present disclosure is not limited thereto. The components only need to exhibit the function of the strained quantum well structure and the optical semiconductor device such as the semiconductor laser according to the present disclosure to achieve the effect.

### INDUSTRIAL APPLICABILITY

The present disclosure can be applied to an optical semiconductor device such as a 2 μm-band laser and an optical receiver supporting a 2 μm wavelength band used for environmental measurement, gas measurement, and the like.

### REFERENCE SIGNS LIST

30, 40 Strained quantum well structure
31, 41 Well layer
32, 42 Barrier layer
43 Band end of conduction band
44 Band end of valence band
45 First quantum level of conduction band
46 First quantum level of valence band
47 Band discontinuity in conduction band
48 Band discontinuity in valence band.

1-7. (canceled)

8. A strained quantum well structure of a type I on an InP crystal substrate and including a luminescence wavelength of 1.9 μm or longer and 2.5 μm or shorter, the strained quantum well structure comprising:
a well layer being an InGaAs, InAs, or InGaAsSb crystal including a compressive strain;
a barrier layer being an InGaAsSb crystal including a tensile strain; and
a band discontinuity in the conduction band being 100 meV or greater.

9. The strained quantum well structure according to claim 8, wherein a band gap of the barrier layer is 0.74 eV or greater.

10. The strained quantum well structure according to claim 9, wherein a composition proportion of Sb of the InGaAsSb crystal of the barrier layer is greater than 0, and the composition proportion of the Sb is less than or equal to 0.47.

11. The strained quantum well structure according to claim 8, wherein a composition proportion of Sb of the InGaAsSb crystal of the barrier layer is greater than 0, and the composition proportion of the Sb is less than or equal to 0.47.

12. The strained quantum well structure according to claim 8, wherein the tensile strain of the InGaAsSb crystal of the barrier layer is 0.4% or more and 1.0% or less.

13. The strained quantum well structure according to claim 8, wherein a layer thickness of the well layer is 5 nm or greater and 12 nm or less.

14. An optical semiconductor device comprising a strained quantum well structure, the strained quantum well structure comprising:
a well layer being an InGaAs, InAs, or InGaAsSb crystal including a compressive strain;
a barrier layer being an InGaAsSb crystal including a tensile strain; and
a band discontinuity in the conduction band being 100 meV or greater, wherein the strained quantum well structure is type I and includes a luminescence wavelength of 1.9 μm or longer and 2.5 μm or shorter.

15. The optical semiconductor device of claim 14, wherein the strained quantum well structure is on an InP substrate.

16. The optical semiconductor device of claim 14, wherein a band gap of the barrier layer is 0.74 eV or greater.

17. The optical semiconductor device of claim 14, wherein a composition proportion of Sb of the InGaAsSb crystal of the barrier layer is greater than 0, and the composition proportion of the Sb is less than or equal to 0.47.

18. The optical semiconductor device of claim 14, wherein the tensile strain of the InGaAsSb crystal of the barrier layer is 0.4% or more and 1.0% or less.

19. The optical semiconductor device of claim 14, wherein a layer thickness of the well layer is 5 nm or greater and 12 nm or less.

20. A semiconductor laser comprising a strained quantum well structure, the strained quantum well structure comprising:
a well layer being an InGaAs, InAs, or InGaAsSb crystal including a compressive strain;
a barrier layer being an InGaAsSb crystal including a tensile strain; and
a band discontinuity in the conduction band being 100 meV or greater, wherein the strained quantum well structure is type I and includes a luminescence wavelength of 1.9 μm or longer and 2.5 μm or shorter, and wherein the semiconductor laser is a 2 μm-band semiconductor laser.

21. The semiconductor laser of claim 20, wherein the strained quantum well structure is on an InP substrate.

22. The semiconductor laser of claim 20, wherein a band gap of the barrier layer is 0.74 eV or greater.

23. The semiconductor laser of claim 20, wherein a composition proportion of Sb of the InGaAsSb crystal of the barrier layer is greater than 0, and the composition proportion of the Sb is less than or equal to 0.47.

24. The semiconductor laser of claim 20, wherein the tensile strain of the InGaAsSb crystal of the barrier layer is 0.4% or more and 1.0% or less.

25. The semiconductor laser of claim 20, wherein a layer thickness of the well layer is 5 nm or greater and 12 nm or less.
